(19) United States
(12) Patent Application Publication
(10) Pub. No.: US 2007/0028960 A1
(43) Pub. Date: Feb. 8, 2007

(54) Active cooling device

(75) Inventors: Anja Royne, Jar (NO); Christopher J. Dey, Sydney (AU)

Correspondence Address: WOOD, PHILLIPS, KATZ, CLARK & MORTIMER, 500 W. MADISON STREET, SUITE 3800, CHICAGO, IL, 60661, US

(73) Assignee: The University of Sydney

(21) Appl. No.: 11/196,609

(22) Filed: Aug. 3, 2005

(51) Int. Cl. H01L 31/00

(52) U.S. Cl. 136/259; 136/243

(57) ABSTRACT

An impinging liquid jet or jets cooling device and a method of designing an impinging liquid jet or jets cooling device is disclosed. The device is arranged such that drainage of a jet liquid is in a direction substantially perpendicular to a surface to be cooled.

### FIELD OF INVENTION

The present invention relates broadly to an impinging liquid jet or jets cooling device, and to a method of designing an impinging liquid jet or jets cooling device.

### BACKGROUND

Active cooling devices are used in a variety of applications including in mechanical applications such as turbine cooling, in electronics applications such as cooling of integrated circuits (ICs) or in cooling of photovoltaic cells under concentrated illumination. Concentration of sunlight onto photovoltaic (PV) cells, and the consequent replacement of expensive photovoltaic area with less expensive concentrating mirrors or lenses, is seen as one method to lower the cost of solar electricity. However, only a fraction of the incoming sunlight striking the cell is converted into electrical energy. The remainder of the absorbed energy is converted into thermal energy in the cell and may cause the junction temperature to rise unless the heat is efficiently dissipated to the environment.

The total energy output of the collector is increased if the thermal energy can be used, for example as domestic hot water or low temperature process heat. The power required of any active component of the cooling circuit is a parasitic loss to the system, and should thus be kept to a minimum. Presently, operating cooling systems with densely packed cells rely on active cooling. One such system is described in Lasich (Lasich, J. B. (2002) Cooling circuit for receiver of solar radiation. PCT Patent Publication No. WO02080286) and uses a water cooling circuit for densely packed solar cells under high concentration. The circuit is said to be able to extract up to 500 kW/m² from the photovoltaic cells, and to keep the cell temperature at around 40° C. for normal operating conditions. This concept is based on water flow through small, parallel channels in thermal contact with the cells. Vincenzi et al. (Vincenzi, D., Bizzi, F., Stefancich, M., Malagu, C., Morini, G. L., Antonini, A. and Martinelli, G.; Micromachined silicon heat exchanger for water cooling of concentrator solar cells; PV in Europe Conference and Exhibition—From PV technology to Energy Solutions, Rome (2002)) have suggested integrating the cooling function in the cell manufacturing process by using a silicon wafer with microchannels circulating water directly underneath the cells. The Vincenzi system under consideration is designed for a concentration level of about 120 suns.

One problem associated with such systems that utilize a form of micro-channel liquid cooling is the high flow resistance exhibited by the micro-channels, which in turn increases the pumping power required to operate the cooling system, thus reducing the overall efficiency of the actively cooled photovoltaic system.

Another motivation to improve the performance of cooling systems in that application is that PV cells generally have a higher solar to electric conversion efficiency when the operated at lower temperatures..

A need therefore exist to provide an alternative active cooling system that seeks to address the abovementioned problem.

### SUMMARY

According to a first aspect of the present invention there is provided an impinging liquid jet or jets cooling device arranged such that drainage of a jet liquid is in a direction substantially perpendicular to a surface to be cooled.

The device may comprise a submerged impinging jet or jets.

The device may comprise an orifice plate disposed between first and second chambers of the device, wherein the jets are directed from the first chamber into the second chamber.

The second chamber may comprise a drainage passage for draining the jet liquid.

The drainage passage may be disposed at the sides of the second chamber, and the first chamber is disposed substantially centrally with respect to the second chamber.

The drainage passage may be disposed substantially centrally with respect to the second chamber, and the first chamber is disposed substantially around the drainage passage.

The device may comprise one or more pipes disposed substantially parallel to the surface to be cooled.

The pipes may comprise one or more orifices for generating the jets, the orifices disposed at portions of the respective pipes closest to the surface to be cooled, in use.

The device may further comprise two or more distributed drainage passages formed on sides of the pipes.

The device may further comprise a feeder pipe in fluid communication with the pipes.

The feeder pipe may be disposed substantially perpendicular to the pipes and substantially parallel to the surface to be cooled.

The feeder pipe may comprise one or more orifices for generating the jets, the orifices being disposed at portions of the feeder pipe closest to the surface to be cooled, in use.

The device may further comprise orifice channels formed on sides of the pipes and extending substantially perpendicular to the pipes towards the surface to be cooled for generating the jets.

The pipes may comprise one or more openings for draining the jet liquid through the pipes, the openings being disposed at portions of the resepctive pipes closest to the surface to be cooled, in use.

According to a second aspect of the present invention there is provided an impinging liquid jet or jets cooling device comprising mulitple drainage channels for distributed drainage of an impinging jet liquid in a direction substantially perpendicular to a surface to be cooled.

According to a third aspect of the present invention there is provided a method of designing an impinging liquid jet or jets cooling device for cooling of photovoltaic cells under concentrated illumination, the method comprising selecting a pumping power for the device; and selecting at least one design parameter such that an optimum heat transfer is achieved at the selected pumping power.

The pumping power may be selected based on a function of cell output power minus pumping power.

The parameters may comprise one or more of a group consisting of nozzle diameter, number of nozzles, size of surface to be cooled, distance of nozzles from surface to be cooled, nozzle shape, nozzle pitch, and nozzle array arrangement.

According to a fourth aspect of the present invention there is provided an impinging liquid jet or jets cooling device having a pumping power and comprising at least one design parameter selected such that an optimum heat transfer is achieved at the pumping power.

According to a fifth aspect of the present invention there is provided a photovoltaic cell system comprising a plurality of photovoltaic cells; a concentrator for concentrating sunlight onto the photovoltaic cells; and an impinging liquid jet or jets cooling unit thermally coupled to the photovoltaic cells via an interface comprising a surface and arranged such that drainage of a jet liquid is in a direction substantially perpendicular to the surface.

The impinging liquid jet or jets cooling unit may comprise a plurality of modules, each module coupled to one or more of the photovoltaic cells.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 is a schematic cross sectional view of an active cooling device according to an example embodiment.

FIG. 2 is a schematic cross sectional view of an active cooling device according to an example embodiment.

FIG. 3 is a schematic cross sectional view of an active cooling device according to an example embodiment.

FIG. 4 is a schematic cross sectional view of an active cooling device according to an example embodiment.

FIG. 5 is a schematic cross sectional drawing illustrating flow behaviour under jet nozzles.

FIG. 6 is a schematic cross sectional drawing illustrating flow behaviour under jet nozzles.

FIG. 7 shows the estimated heat transfer coefficient, based on temperature measurements, of an impingement zone under a single impingement jet according to an example embodiment.

FIG. 8 shows plots of the heat transfer coefficient versus scaled radial distance data of FIG. 7.

FIG. 9 shows plots of heat transfer coefficient versus radial distance data of FIG. 7.

FIG. 10 shows the estimated heat transfer coefficient of impingement zones under an array of impingement jets according to an example embodiment.

FIG. 11 shows plots of heat transfer coefficient versus radial distance data of FIG. 10.

FIG. 12 shows a schematic cross sectional view of a plenum chamber illustrating flow characteristics in a plenum chamber according to an example embodiment.

FIG. 13 is a graph showing plots of pressure drop distributions as a function of flow rate for different geometries of nozzles according to example embodiments.

FIGS. 14a (flow rate) and 14b (pressure drop) are graphs showing plots for different geometries of nozzles as a function of average heat transfer coefficients, according to example embodiments.

FIG. 15 is a graph showing plots of average heat transfer coefficients as a function of flow rate for different nozzle geometries, according to example embodiments.

FIG. 16 is a graph showing the predicited Nusselt number dependence on s/d dependents according to the Martin model and the Huber model respectively.

FIGS. 17a and b are graphs showing plots illustrating measured pumping power as a function of average heat transfer coefficients, according to example embodiments, and a comparison with the Martin and Huber models respectively.

FIG. 18 is a graph showing plots of predicted pumping power versus average heat transfer coefficient according to the Martin and Huber models.

FIGS. 19a and b are graphs showing plots of predictions from the Martin and the Huber models respectively for pumping power as a function of nozzles diameter, according to example embodiments.

FIG. 20 is a graph showing plots from the Martin model of the product KG as a function of s/d for a range of z/d.

FIGS. 21a and b are graphs showing plots of pumping power as a function of nozzle diameter according to example embodiments, using the Martin and the Huber models respectively.

FIGS. 22a and b are graphs showing plots of optimal nozzle diameter and required pumping power respectively as functions of heater size, according to example embodiments.

FIG. 23 is a graph showing plots of optimal nozzle diameter as a function of nozzle-to-plate spacing (z/d), according to example embodiments.

FIG. 24 is a graph showing plots of predicted and measured pumping power as a function of average heat transfer coefficient according to example embodiments.

FIG. 25 shows the heat transfer coefficient distribution of impingement zones under an array of impingement jets, according to an example embodiment.

FIGS. 26a to d are graphs showing plots of different power measures as a function of average heat transfer coefficient according to example embodiments, using the Martin (a, c) and Huber (b and d) models respectively, at an illumination of 200 suns (a, b) and 500 suns (c, d).

FIG. 27 is a schematic top sectional view of an active cooling device according to an example embodiment.

FIG. 28 is a schematic exploded top view of components of the device of FIG. 27.

FIG. 29 is a schematic cross sectional view of the device of FIG. 27.

### DETAILED DESCRIPTION

The example embodiments described provide high concentration photovoltaic systems cooling to ensure a high average heat rate transfer across the entire surface. The embodiments utilize a jet impingement cooling device incorporating drainage of the cooling liquid in a direction substantially perpendicular to the heated impingement surface. Different configurations for back drainage are disclosed in different embodiments. While the example embodiment described relate to cooling of PV cells under high concentration, it will be appreciated that the present invention does have broader applications including cooling of mechanical and electronics components and systems. Advantages that may be achieved in example embodiments include an improved space optimisation laterally along a surface to be cooled, and a “straight back” drainage minimising presence of respective volumes of the cooling liquid in the vicinity of the surface to be cooled.

In FIG. 1, in one embodiment water enters into a plenum chamber 100 ending in an orifice plate 102, through which the jets 104 impinge onto the heated surface 106. The water then returns through an outlet cavity 108 which surrounds the plenum chamber 100. An advantage of this embodiment is that the flow patterns under the jet array are thought not to be affected by the drainage flow. While heat may be transferred from the higher temperature water in the return chamber 108 to the plenum chamber 100, because the water spends just a short time in contact with the heated surface 106, the temperature difference is believed to be too small to cause any significant heating in the example embodiment. The plenum chamber 100 and outlet cavity 108 are of substantially cubic shape in the example embodiment, however, it will be appreciated that other shapes may be used in different embodiment, such as e.g. a hexagonal shape.

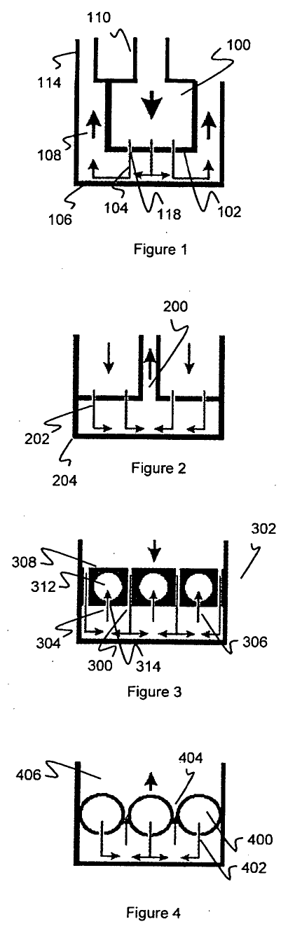

In order to further reduce a likelihood that the area along the edges might experience a lower heat transfer coefficient due to eddy formation along the steep edges of the outlet cavity, or because the jets may not be placed close enough to the edges, another embodiment, shown in FIG. 2, has a central drainage 200 configuration in which it is possible to place the jets 202 close to the edges 204 and thus diminish any eddy formation.

In another embodiment, in order to reduce a possible adverse effect on the overall cooling that crossflow to the drainage may have as the number of nozzles is increased, distributed drainage exits throughout the cooling device are used. With reference to FIG. 3, in one such embodiment the number of nozzles 300 used for the cooling module 302 may be large enough that effects of crossflow become significant. Thus, in this embodiment, distributed drainage exits e.g. 304, 306 are implemented throughout the cooling device. The embodiment has a thick orifice plate 308 through which long nozzles 300 are drilled. Between the rows of nozzles 300, outlet pipes 312 are drilled through the length of the plate 308, perpendicular to the nozzles 300. The spent liquid flows into the outlet pipes 312 through drainage holes 314 along the bottom of the pipes 312.

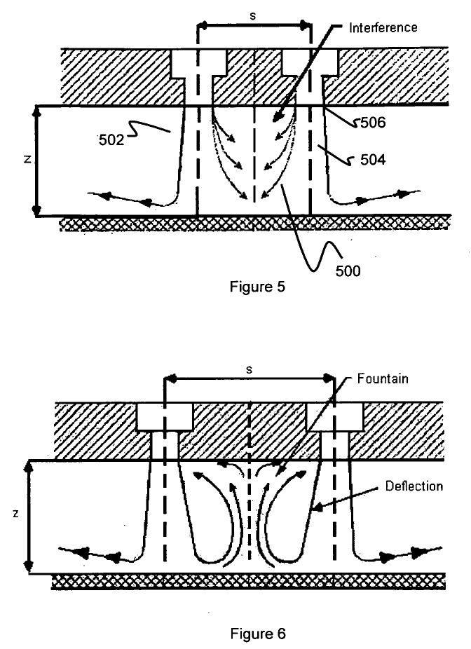

In another embodiment, shown in FIG. 4, the water enters through parallel inlet pipes 400 and impinges through holes 402 along the bottom of the pipes 400. The water is drained through gaps 404 between the pipes 400 into an outlet chamber 406.

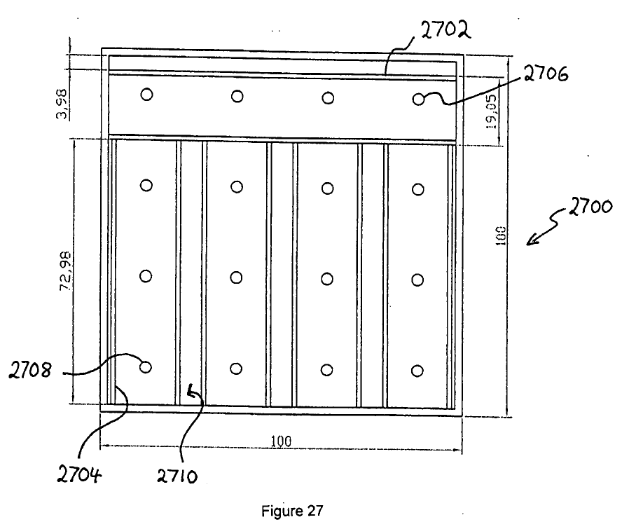

Details of another distributed drainage embodiment will now be described, with reference to FIGS. 27 to 29.

FIG. 27 shows a cross sectional top view of an active cooling device 2700 according to an embodiment. The device 2700 comprises a feeder pipe 2702 in fluid communication with four further pipes e.g. 2704 arranged substantially perpendicular to and along the feeder pipe 2702. The feeder pipe 2702 and each of the pipes 2704 comprise nozzles e.g. 2706 and 2708 for directing respective impingement jets towards a surface 2710 of the device 2700. During installation, the surface 2710 of the device 2700 is arranged in thermal contact with the photovoltaic cell array to be cooled (or a portion thereof).

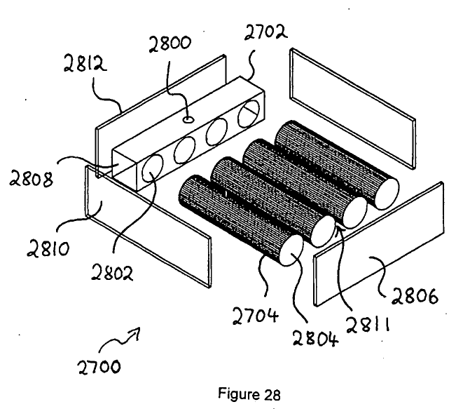

FIG. 28 shows a perspective exploded view of the device 2700 with the top and bottom covers of the device 2700 removed. The feeder pipe 2702 comprises an opening 2800 for liquid inlet. The pipes 2704 are sealingly fitted to respective openings 2802 in the feeder pipe 2702. The other ends e.g. 2804 of the pipes 2704 are sealed through panel 2806 when the device 2700 is assembled. Similarly, the side openings e.g. 2808 of the feeder pipe 2702 are sealed by respective panels e.g. 2810 when the device 2700 is assembled.

In operation, distributed drainage in a direction substantially perpendicular to the surface to be cooled is achieved through the gaps e.g. 2811 between the respective pipes 2704, between the outer inlet pipes e.g. 2704 and the panels e.g. 2810, and between the feeder tube 2702 and panel 2812.

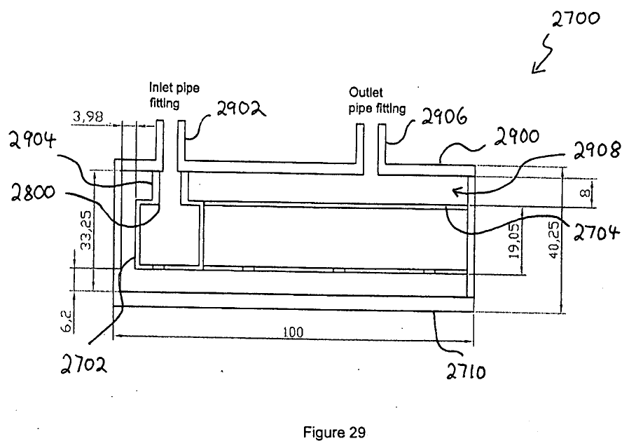

FIG. 29 shows a cross-sectional view of the device 2700 with a bottom cover 2710 and a top cover 2900 fitted. The top cover 2900 comprises an inlet pipe fitting 2902 aligned with and sealingly connected to an intermediate pipe fitting 2904 which in turn is sealingly connected to the opening 2800 of the feeder tube 2702. An outlet pipe fitting 2906 is also provided for drainage of liquid from the drainage chamber area 2908 above the pipes e.g. 2704.

In the example embodiment, for cooling of large surfaces, arrays of multiple nozzles are used. Submerged jets in an array interact with each other in two fundamental ways. The first is interference between the mixing regions 500 of the two jets 502, 504 before impingement as shown in FIG. 5. This phenomenon is most pronounced at close jet-to-jet spacings s/d, where d is the lower diameter 506 of the nozzle, and at high z/d values due to mixing region 500 expansion beneath the jet exit. The effect of this interference is believed to be a weakened jet and a subsequent lowering of the overall heat transfer. On the other hand, it has been suggested that the jet interference may lead to a higher heat transfer because of the increase in turbulence level. This second effect occurs when two wall jets 600, 602 meet face-to-face, as illustrated in FIG. 6. If the jets 600, 602 are otherwise equal, this interaction occurs along the centreline 604 between two adjacent jets 600, 602. At low flow rates and large s/d, it will result in increased turbulence and higher heat transfer in the region 606 of interaction. At high jet velocities, however, the interaction can become strong enough to cause a jet fountain 608 to form. This can cause heated liquid to re-enter the core of the jets 600, 602 and result in a lower overall heat transfer under the array.

The local heat transfer and flow structure characteristics of single impinging jets have been studied extensively. The exact shape of the local heat transfer distribution has, however, not been successfully correlated because it is such a complex function of Reynolds number, nozzle diameter, d, nozzle-to-plate spacing, z, nozzle pitch, s, and nozzle configuration. The nozzle configuration has a significant influence on the heat transfer because it determines the level of turbulence in the flow. More accurate correlations exist for the stagnation point and average heat transfer coefficients of single jets. In jet arrays, adjacent jets can interfere destructively prior to impingement and either constructively or destructively where the two wall jets meet, depending on Reynolds number, nozzle pitch and nozzle-to-plate spacing. A number of different correlations predict the average heat transfer coefficient under arrays of jets with different ranges of validity. Surface modifications have been found to increase the average heat transfer coefficient by as much as a factor of three for water jets, and more for liquids with higher Prandtl number. However, some methods of surface modifications can lead to a decrease in heat transfer. Other methods of disturbing the flow such as inserting mesh screens or a perforated plate have shown the same trend of mostly increasing, but sometimes decreasing, the average heat transfer coefficient.

In the following, experimental test results of three different single jet orifice plates will be discussed. The plates were tested in an experimental setup corresponding to the side-drainage jet configuration of the example embodiment described above with reference to FIG. 1. Table 1 gives a summary of the parameters used for the single jet plates, labeled S1, S2, S3 respectively.

TABLE 1

| | | | Nozzle-to- | | |
|---|---|---|---|---|---|
| | Number of | Nozzle diameter | plate spacing | Nozzle | |
| Device | nozzles N | d (mm) | [symbol] d | pitch s/d | Nozzle configuration |
| single S1 | 1 | 1.5 | 3.33 | — | [symbol] [symbol] |
| single S2 | 1 | 2.0 | 2.50 | — | [symbol] [symbol] |
| single S3 | 1 | 2.5 | 2.00 | — | [symbol] [symbol] |

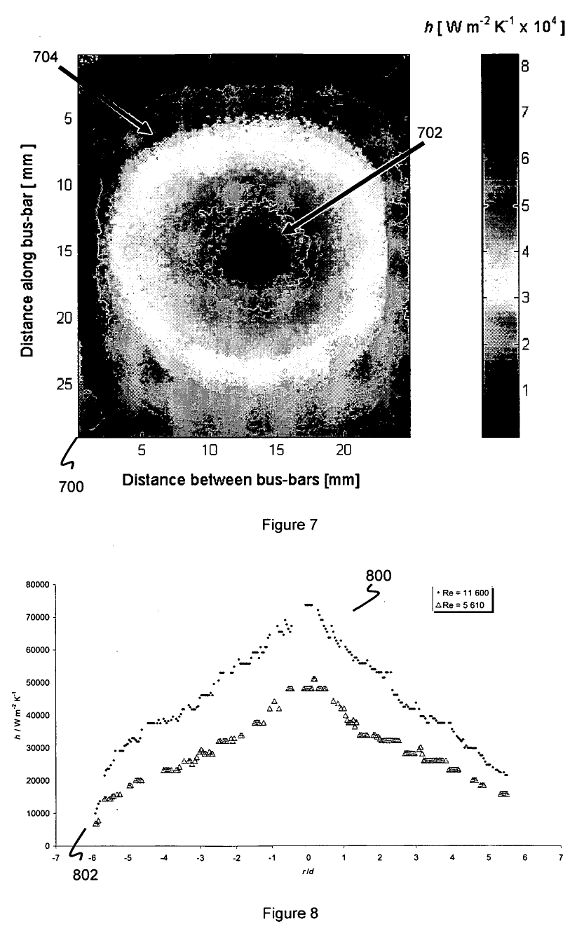

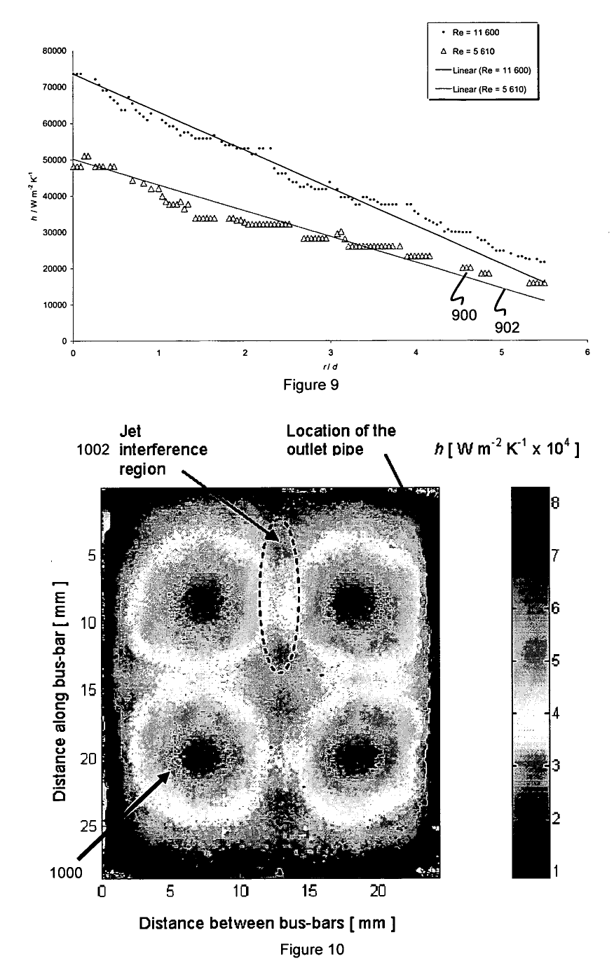

FIG. 7 shows a heat transfer distribution 700 under a single jet 702. While being quite symmetrical around the centre, the perimeter region e.g. 704 appears ‘flattened’. A clearer representation of the local heat transfer distribution is given by the cross-section through the impingement area (shown in FIG. 8). The impingement zone 800 (r/d<1) is seen to be characterised by a region of high heat transfer in the centre followed by a sharp drop at about r/d−0.4. For r/d>1, the local heat transfer drops off monotonically. As shown in FIG. 9, the shape of the heat transfer curve 900 can be estimated reasonably well by a linear function 902, which reaches the value of half maximum at r/d−3.5, as follows:

$$h = {h}_{max} ( 1 - \frac{1}{7} r / d ) . \qquad ( 1 )$$

This simplification helps to facilitate the estimation of temperature variations across the heated surface. Another interesting aspect of FIG. 8 is the dramatic drop in heat transfer near the edge which is visible e.g. on the left hand side 802 of the graph. The drop in heat transfer coefficient is most likely caused by eddy formation along the steep edges of the outlet cavity.

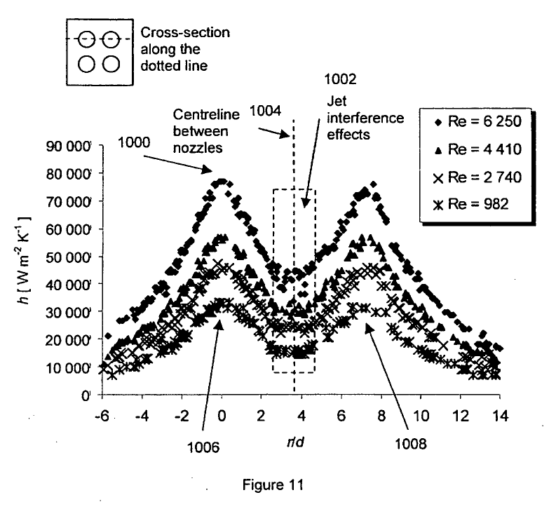

The distribution of local heat transfer for each individual jet in an array was found to be similar to that of a single jet. With reference to FIGS. 10 and 11, the heat transfer coefficient drops off monotonically with radial distance away from the stagnation point 1000 and reaches a value of half that of the stagnation point at about r/d˜3.5. The “stagnation point” is generally referred to as the point directly underneath the centre of the nozzle. This is sometimes also referred to as the “impingement point”. “Impingement zone” refers to the area close to the stagnation point.

However, as expected, interactions between the jets lead to some heat transfer characteristics that are different from those of single jets. FIG. 10 presents a heat transfer coefficient distribution for an array of four nozzles, while FIG. 11 shows a cross-section of the local heat transfer coefficient through two stagnation points for a range of Reynolds numbers. One of the characteristics of jets in an array is a slight asymmetry in the outer jets. The heat transfer distribution is found to drop off more steeply towards the middle of the array than towards the outside. The reason for this is believed to be that the jet experiences less restriction in the outward direction, and is thus decelerated more slowly. No systematic difference in local heat transfer distribution could be found between individual nozzles of different placements within the array.

In FIGS. 10 and 11, a region 1002 of enhanced heat transfer in the area along the centreline 1004 between the nozzles is indicated. This region was observed for all Reynolds numbers in both nine and four nozzle arrays. The pattern is believed to be caused by increased turbulence where the neighbouring wall jets meet head-on. The heat transfer coefficient profiles in FIG. 11 show that this interaction region 1002 extends about 0.6-1.2 nozzle diameters away from the centreline 1004 between the jets 1006, 1008. This value was found to be relatively constant for all the four-nozzle arrays tested, while it extended about 1.5 nozzle diameters for the nine-nozzle arrays. Where the interaction region 1002 starts, the heat transfer distribution stops decreasing and instead increases slightly towards the centreline 1004.

Oscillations were clearly observed for all of the four-nozzle arrays. In nine-nozzle arrays some flow instability was observed around the perimeter of the array, but not to the same extent as with the four nozzles arrays. This might be related to the poorer spatial resolution of the measurements with the smaller nozzles. The oscillations observed in the four-nozzle arrays were characterised by the interaction region between the jets not being constant along the centreline, but shifting slightly toward the stagnation point of one jet and then the other in an irregular manner. The positions of maximum heat transfer at the stagnation points of the jets remained constant. The oscillations were not regular enough to enable an accurate analysis of amplitude and frequency to be performed with the current experimental setup. The amplitude of the movement was found to be about 1.5 mm. The frequency of the oscillations could not be established. No significant difference in oscillation pattern could be found between the different nozzle configurations.

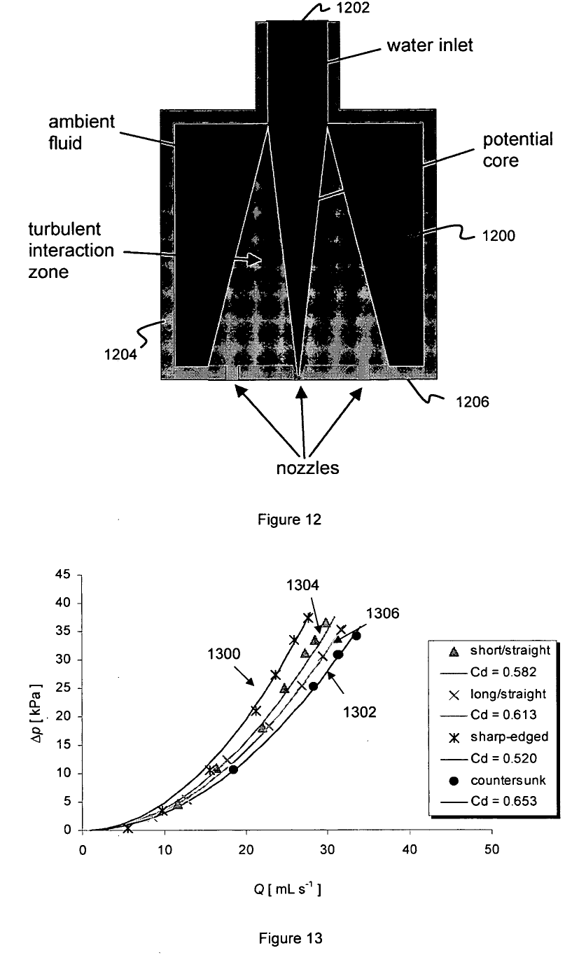

One possible reason for the oscillations could be the remaining structure of the jet 1200 which is formed at the inlet 1202 of the plenum chamber 1204, as shown in FIG. 12. The orifice plate 1206 is located a distance of 4.9 inlet diameters beneath the water inlet 1202 in example embodiments tested. At this distance, the inlet jet 1200 is likely to have much of its original structure left. The oscillations probably arise due to temporal structures in the turbulence of the jet 1200 propagating through the orifice plate 1206 and thus there were always some particles present. The presence or absence of a filter may be a factor for the minimum safe nozzle diameter to avoid blocking of nozzles in practical jet device embodiments.

It has been recognized by the inventors that in designing a jet impingement device, it is not only the flow rate which is important, but also the pressure drop through the device. The preferred cooling system will in many cases be the one that delivers the highest rate of cooling at a given pumping power. The total pumping power is proportional to the product of flow rate and pressure drop. The pressure drop through the various models can be predicted from theory. Bernoulli's equation gives the relationship between liquid velocity, gravitational head and pressure for an incompressible liquid in steady flow as

$${gz}_{1} + \frac{{p}_{1}}{ρ} + \frac{{v}_{1}^{2}}{2} = {gz}_{2} + \frac{{p}_{2}}{ρ} + \frac{{v}_{2}^{2}}{2} , \qquad ( 2 )$$

where subscripts 1 and 2 refer to conditions immediately before and after the orifice, respectively and ρ is the fluid density. This can be used to find the pressure difference across the orifice. Assuming the height difference is negligible across the orifice, the z-term can be left out. This is justifiable because, for the minimum flow rate of measurements using the example embodiments, gΔz/Δv2=3×10⁻³, v₁ was also sufficiently small compared with v₂ to be ignored. The resulting expression for pressure drop Δp becomes

$$Δ p = \frac{ρ}{2} {v}_{2}^{2} . \qquad ( 3 )$$

With reference to FIG. 1, other pressure drops through the jet device in an example embodiment include the contraction from supply pipe to inlet pipe 110, expansion from inlet pipe 110 to jet chamber 100, expansion after orifice plate 102, deflection at impingement plate 104 and in outlet chamber 106, contraction to outlet cavity 108 and expansion from outlet cavity 108 to drainage pipe 114. These are all at least two orders of magnitude smaller than the pressure drop through the orifice 102 and can thus be ignored.

The velocity after the orifice was found using the area of the vena contracts instead of the nozzle area. The vena contracta refers to the phenomenon of a jet continuing to contract for some distance after exiting the nozzle. Thus, the resulting cross-sectional jet 104 area is smaller than the nozzle 118 area. The vena contracts arises because of a transverse pressure gradient between the edge and centre of the nozzle. The pressure at the centre is higher than the ambient pressure at the edge, which causes the jet to continue to accelerate after leaving the nozzle until ambient pressure is achieved throughout the cross-section. The area of the vena contracts is determined by the nozzle geometry, which is characterised by the contraction coefficient C_{c}, given as

$${C}_{c} = \frac{{A}_{c}}{{A}_{n}} = \frac{{ⅆ}_{c}^{2}}{{ⅆ}_{n}^{2}} . \qquad ( 4 )$$

The value of C_{c} is ≈0.6 for a perfectly sharp lip, and rises to C_{c}≈1 for a bell-mouthed opening. From theoretical limitations, the absolute limits for the contraction coefficient are 0.5≦C_{c}≦1. Taking into account the losses through the orifice, the theoretical velocity is reduced by a factor Cᵥ called the velocity coefficient, defined as the ratio of actual to theoretical velocity at the orifice exit. Typical values for Cᵥ lie between 0.95 and 0.99. Because Cᵥ and C_{c} are difficult to measure independently, they are often combined to a discharge coefficient C_{d}=CᵥC_{c}.

The resulting expression for pressure drop through the device is

$$Δ p = \frac{1}{2} ρ {v}_{2}^{2} = \frac{1}{2} ρ \frac{{Q}^{2}}{{C}_{d}^{2} {A}_{2}^{2}} = ρ {Q}^{2} \frac{8}{{N}^{2} {π}^{2} {C}_{d}^{2} {d}^{4}} . \qquad ( 5 )$$

The discharge coefficient is known to vary slowly with Reynolds number, and can be assumed constant for the range of Re in the different example embodiments. A least-square fitting to the experimental data gave the discharge coefficients C_{d} given in Table 2.

TABLE 2

| Nozzle configuration | C_{d} |
|---|---|
| short/straight | 0.582 |
| long/straight | 0.613 |
| sharp-edged | 0.520 |
| countersunk | 0.653 |

The pressure drop distributions as a function of the correlations are shown in FIG. 13. The coefficients of determination for all correlations were R²≧0.969. As the expected values for C_{d} lie in the range 0.6×0.95−1.0×0.99=0.57−0.99, the experimental values for the example embodiments are quite low. In fact, the value obtained for the sharp-edged nozzle (curve 1300) lies outside the expected range, although it is not below the theoretical limit of 0.5×0.95=0.475. Comparing the different four-nozzle arrays (curves 1300, 1302, 1304 and 1306), C_{d} is found to be highest for the countersunk (curve 1302) and lowest for the sharp-edged nozzle (curve 1300). The straight nozzles (curves 1304, 1306) are both intermediate cases. The difference in discharge coefficient for the straight (curves 1304, 1306), contoured (curve 1302) and sharp-edged nozzles (curve 1300) can be explained by the degree of sharpness at the flow inlet. In addition, the measured C_{d} is lower for the short/straight nozzle (curve 1304) than for the long/straight nozzle (curve 1306). At higher length-to diameter (//d) values, the separated flow at the nozzle entrance reattaches within the nozzle, and the reduction of the effective nozzle area is eliminated. This change in effective nozzle area would also explain the smaller pressure drop through the longer nozzles. In the example embodiments, //d=0.7 for the short/straight and (curve 1304) 1.4 for the long/straight nozzle (curve 1306).

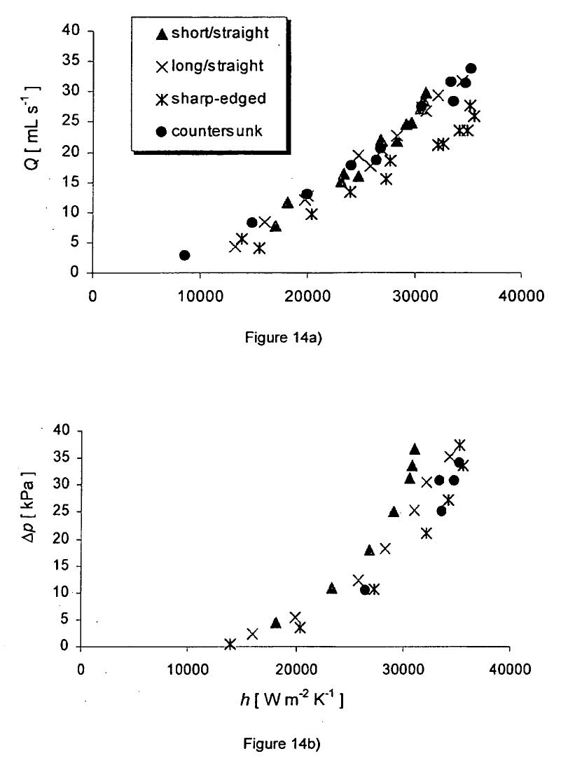

As discussed above, the optimal nozzle configuration in embodiments of the present invention for a given system will be determined by two factors: the required pressure drop and the flow rate required to achieve a given average heat transfer coefficient. In one embodiment, to improve the performance of an orifice plate with simple straight nozzles, the holes are countersunk to reduce the pressure drop, thereby achieving a higher heat transfer coefficient at the same pumping power. In another embodiment, the holes are made sharp-edged to achieve a higher heat transfer at a comparable flow rate. FIGS. 14a and b show how the flow rate and pressure drop respectively were found to vary with average heat transfer coefficient for the various four-nozzle arrays in example embodiments. It can be seen that, to achieve a given heat transfer coefficient, the short/straight nozzles involve the highest pressure drop. The long/straight nozzles perform a little better, while the results for the countersunk and sharp-edged nozzles are virtually indistinguishable. This may relate to the fact that while the sharp-edged nozzles yield a higher pressure drop at a given Reynolds number, they also are better in terms of higher heat transfer coefficient at lower Reynolds numbers. At the same time, the sharp-edged orifices require a lower flow rate for a given heat transfer coefficient than the other orifices. This lead to the recognition that for a given pumping power, the nozzle configurations yield increasing average heat transfer coefficients in the order: short/straight, long/straight, countersunk and finally sharp-edged.

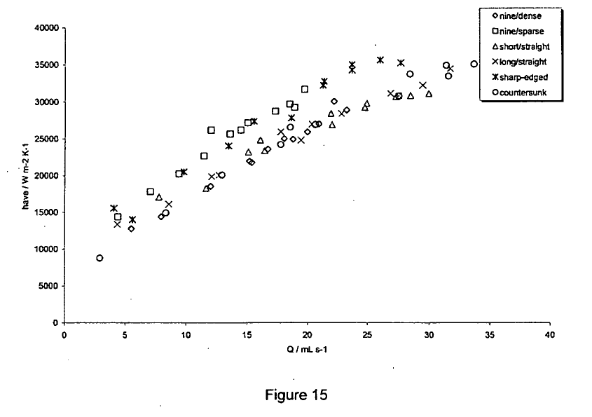

A good indication of the pumping power required for the various orifice plates is illustrated by the maximum average heat transfer coefficients, shown for each configuration in FIG. 15. The values for the highest achieved h_{avg} and Q are also given in Table 3 for easier comparison.

TABLE 3

| | Maximum Q | Maximum h_{avg} |
|---|---|---|
| Device | (mL s⁻¹) | (10⁴ W m⁻² K⁻¹) |
| nine-nozzle | 23.2 ± 1.2 | 2.9 ± 0.2 |
| short/straight | 29.9 ± 1.5 | 3.1 ± 0.3 |
| long/straight | 31.7 ± 1.6 | 3.4 ± 0.3 |
| sharp-edged | 27.7 ± 1.4 | 3.5 ± 0.3 |
| countersunk | 33.3 ± 1.7 | 3.5 ± 0.3 |

The maximum flow rate for each device is achieved when the valve is fully open, so that the flow circuit outside the jet device itself is identical. These values therefore correspond to the same pumping power. Comparing the short and long straight nozzles, the decrease in pressure drop and the corresponding increase in flow rate for the longer nozzles result in a higher maximum heat transfer coefficient for the longer nozzle, which would imply that //d>1 is the preferable configuration for straight nozzles. The countersunk and sharp-edged nozzles yield maximum heat transfer coefficients which can not be distinguished within the range of uncertainty. However, as the sharp-edged nozzle yields this result at a considerably lower flow rate, this could be the preferable option in many systems.

The results obtained for the impinging jet device according to embodiments of the present invention are highly promising when comparing to previously reported results for microchannel devices. The highest average heat transfer coefficient obtained in the experiments was h=3.5×104 W m⁻² K⁻¹ which is equivalent to a thermal resistance of R=2.9×10-5 K m² W⁻¹. At the same time, the pressure drop through the device example embodiments to achieve a given heat transfer coefficient is about an order of magnitude lower than what is typical for existing microchannel devices.

In the following, optimization rules for impinging jet devices embodying the present invention will be described.

The pumping power W required for any forced convection device is given as the product of flow rate Q and pressure drop p,
W=ΔpQ. (6)

The pressure drop through an orifice was found to be correlated by

$$Δ p = ρ {Q}^{2} \frac{8}{{N}^{2} {π}^{2} {C}_{d}^{2} {d}^{4}} . \qquad ( 7 )$$

Equation (7) can be substituted directly into Equation (6). In the subsequent sections it will be assumed that C_{d} is independent of nozzle diameter.

Next, the flow rate Q is sought to be eliminated. This was done by including the correlation for average heat transfer coefficient h_{avg} in terms of Q, solving for Q, and substituting this into Equation (6). Several correlations exist that may be used for the heat transfer part of the model. It was decided to use two different models with different s/d dependence. The first is the Martin [Martin, H. (1977) Heat and mass transfer between impinging gas jets and solid surfaces. Advances in Heat Transfer 13, 1-60] correlation. The second model, which will be referred to as the Huber model, incorporates the constant C and Reynolds number dependence m from experimental data obtained using example embodiments with the Prandtl-number dependence from Li and Garimella [Li, C.-Y. and Garimella, S. V. (2001) Prandtl-number effects and generalized correlations for confined and submerged jet impingement. International Journal of Heat and Mass Transfer 44 (18), 3471-3480] and the s/d dependence from Huber and Viskanta [Huber, A. M. and Viskanta, R. (1994) Effect of jet-to-jet spacing on convective heat transfer on confined, impinging arrays of axisymmetric jets. International Journal of Heat and Mass Transfer 37 (18), 2859-2869].

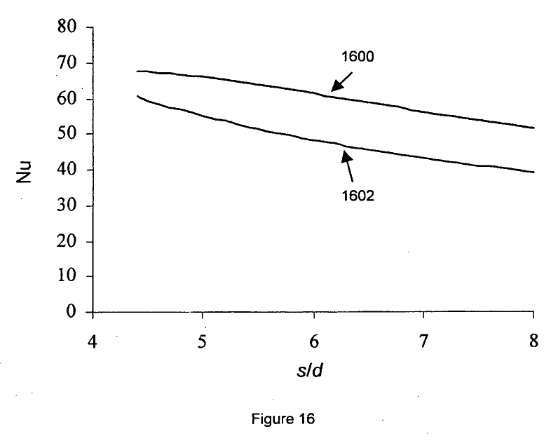

As seen in FIG. 16, the two chosen models are qualitatively different with respect to their s/d dependence. The Martin model (curve 1600) has a negative second derivative, while the Huber model (curve 1602) has the opposite shape. This will be shown to result in quite different behaviours for the pumping power correlations made using these models.

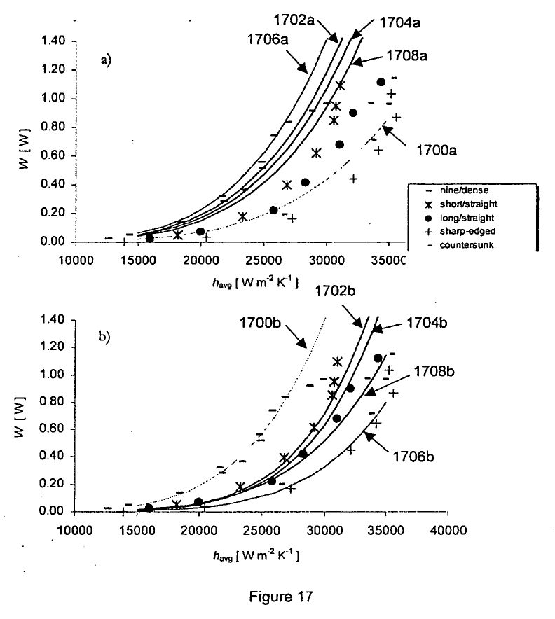

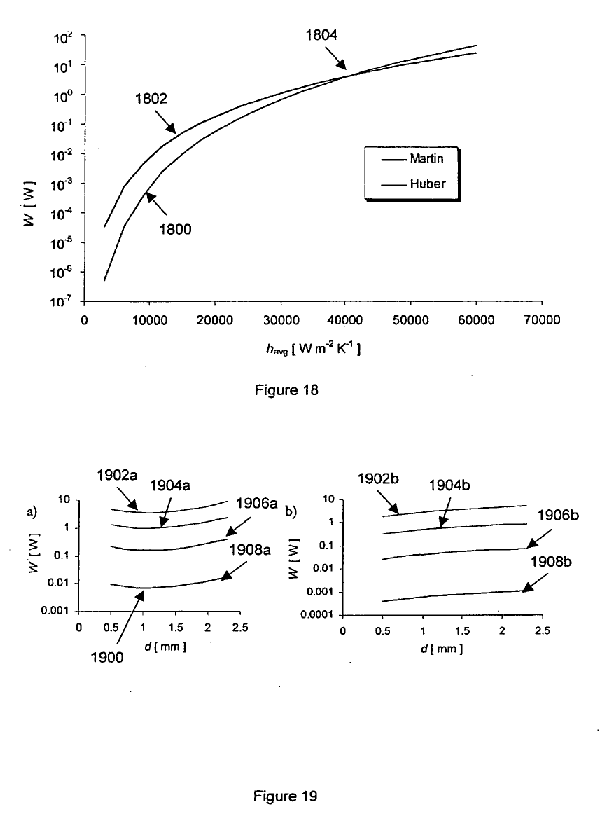

FIGS. 17a and b show comparisons of experimental results obtained using impinging jet devices according to embodiments of the present invention with theoretical predictions from the Martin and Huber models respectively. In FIGS. 17a and b, curves 1700a and b are for the nine/dense model, curves 1702a and b are for the short/straight model, curves 1704a and b are for the long/straight model, curves 1706a and b are for the sharp-edged model, and curves 1708a and b are for the countersunk model. It was found that the Martin model (FIG. 17a) does not quite fit the experimental values. This is believed to be because the Martin model underestimates the heat transfer coefficient for the four-nozzle arrays and overestimates it for the nine-nozzle arrays. The Huber model (FIG. 17b) on the other hand fits the data closely because it is built on the experimental results. The slopes of the two correlations are quite different, and this becomes apparent if they are compared for a similar device over a range of heat transfer coefficients, as shown in FIG. 18. Outside the range of the experimental data, the two lines 1800, 1802 cross over (numeral 1804) and the Huber model 1800 starts to predict higher W levels than the Martin model 1802. These observations show how important it is to have accurate values for the characteristics of the orifice types under consideration in order to make reliable predictions. Preferably, the discharge coefficient C_{d} as well as the Reynolds number dependence for respective embodiments should be determined experimentally.

The major difference between the predictions from the Martin model and the Huber model is illustrated in FIGS. 19a and b. While the former (FIG. 19a) predicts a definite optimal nozzle diameter (minimum e.g. 1900), dₒₚₜ, for a set of conditions, the latter (FIG. 19b) recommends always using the smallest possible nozzles. In FIGS. 19a and b, curves 1902a and b are h_{avg}=40000, curves 1904a and b are h_{avg}=30000 curves 1906a and b are h_{avg}=20000, and curves 1908a and b are h_{avg}=10000. This discrepancy arises from the difference in s/d dependency for the Martin and Huber correlations shown in FIG. 16. It is the “K” and “G” correction factors of the Martin correlations that lead to an optimum pitch value (s/d)ₒₚₜ, which, since s/d is a function of Lₕₑₐₜ, N and d, gets translated into an optimum nozzle diameter. K and G are functions for s/d and z/d only, and will therefore predict an (s/d)ₒₚₜ for each value of z/d.

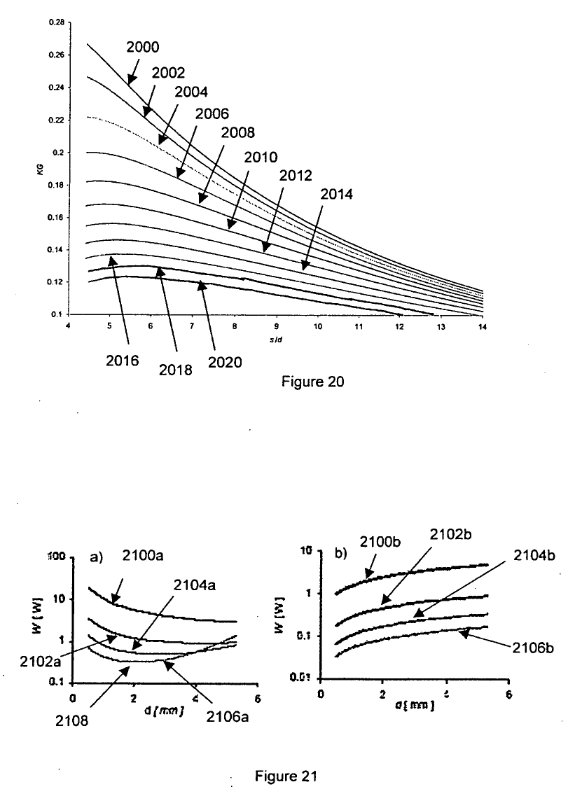

FIG. 20 shows how the product KG varies with s/d within the z/d range of validity (curve 2000 z/d=2; curve 2002 z/d=3; curve 2004 z/d=4; curve 2006 z/d=5; curve 2008 z/d=6; curve 2010 z/d=7; curve 2012 z/d=8; curve 2014 z/d=9; curve 2016 z/d=10; curve 2018 z/d=11; curve 2020 z/d=12). In all cases, (s/d)ₒₚₜ<6, and for the lower values of z/d there is no optimum to be found. However, the values of dₒₚₜ and the corresponding (s/d)ₒₚₜ predicted from the pumping power correlation (see FIG. 19a) were found a not coincide with the optimal s/d shown in FIG. 20. This lead to the recognition that the optimum nozzle diameters predicted are determined by an interaction between the pressure drop and heat transfer correlations according to example embodiments. It was recognized that as the nozzle diameter is decreased, the increase in jet velocity leads to a higher heat transfer coefficient. This, however, comes at the cost of a highly increased pressure drop.

Moreover, the heat transfer distribution drops off more rapidly away from the impingement point. It was recognized that at some specific diameter, the negative effects become dominant and lead to an increased pumping power for a given h_{avg}. Both models predict a lower pumping power for a higher number of nozzles, independent of other variables. This result is contrary to the conclusions from several existing studies that optimise against flow rate. It was recognized that increasing the number of nozzles and thereby reducing s/d is beneficial to the average heat transfer coefficient. However, when the jets are too closely spaced, the negative effects of jet interaction before impingement (discussed above) become increasingly significant. Beyond a certain s/d, the benefit gained by adding nozzles is lost to increased jet interference. The Huber and Martin models as used according to example embodiments are believed to be valid down to s/d=4 and s/d=4.43, respectively. A spacing of s/d=4 seems therefore to be a reasonable lower limit for design purposes.

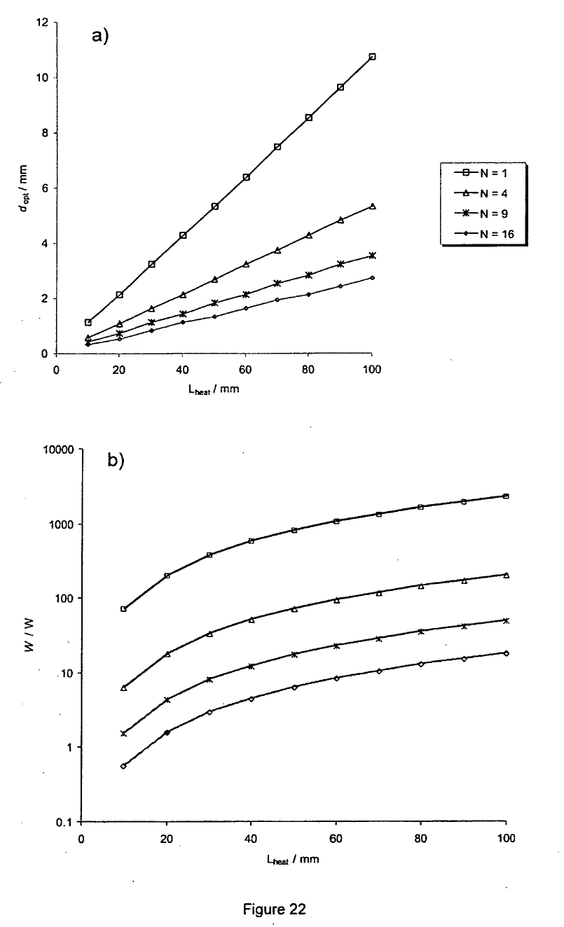

The predicted pressure drop variation with nozzle diameter is shown in FIGS. 21a and b and for a range of N. The Huber model (FIG. 21b, curve 2100b N=1; curve 2102b N=2, curve 2104b N=9, curve 2106b N=15) predicts the smaller nozzles to be superior under all conditions, and shows no difference in trend for the different numbers of nozzles. The Martin model (FIG. 21a, curve 2100a N=1; curve 2102a N=2, curve 2104a N=9, curve 2106a N=15), on the other hand, predicts an optimum nozzle diameter (minimum e.g. 2108) which shifts towards smaller nozzles for increasing N. The latter is believed to be because with fewer nozzles, a larger area has to be covered by each jet. Increasing the nozzle diameter makes the local heat transfer distribution fall off more slowly away from the stagnation point in terms of absolute distance, so that a larger area is covered by the central high heat transfer region. The optimal nozzle diameter, dₒₚₜ, is found to be independent of h_{avg}, C_{d} and Pᵣ. However dₒₚₜ, was found to depend on N and Lₕₑₐₜ as shown in FIGS. 22a. FIG. 22b shows the required pumping power per area W/A for h_{avg}=10⁴ W m⁻² K⁻¹ to illustrate the large variation in pumping power for an increasing number of nozzles. Note that W/A also increases with the heater size. This reflects back on the benefit of a high number of nozzles per area. As N is kept constant but the area is increased, W/A increases as well.

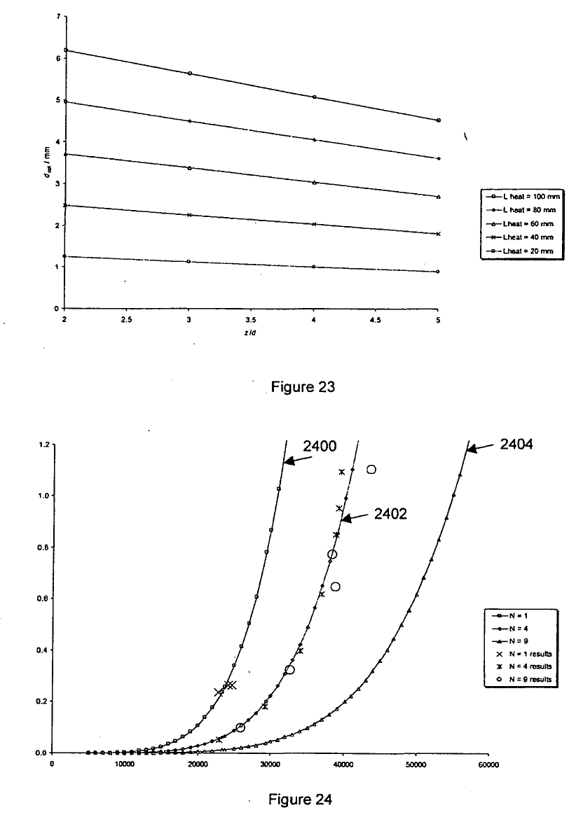

The optimal nozzle diameter in example embodiments is also dependent on the nozzle-to-plate spacing z/d as shown in FIG. 23. It can be seen that dₒₚₜ decreases linearly with increasing z/d. The slope of the graph is found to be dependent on N but independent of Lₕₑₐₜ. The value of s/d at dₒₚₜ was calculated for the examples embodiments. It was found to vary with z/d only, and not to drop below the critical value of s/d=4.

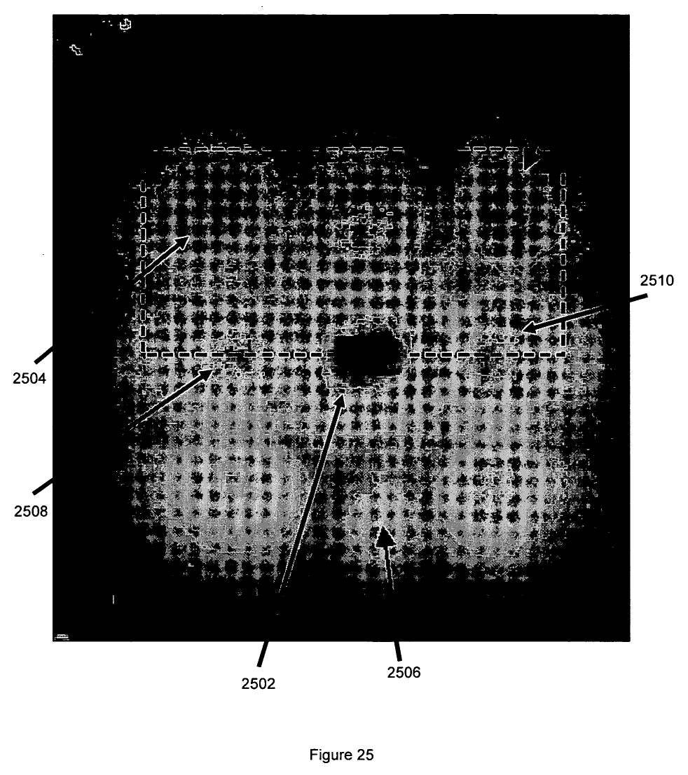

Both the Martin and the Huber models predict that for a given pumping power, a higher h_{avg} will be achieved with a greater number of nozzles, provided s/d>4. FIG. 24 shows the predicted curves 2400, 2402, 2404 for the various numbers of nozzles in different embodiments. The N=4 results are calculated from the measured heat transfer coefficient distributions, and the corresponding curve is calculated for this water temperature. The predictions shown in FIG. 24 are thus all for different water temperatures and different Lₕₑₐₜ and can therefore not be directly compared against each other. The values of h_{avg} and W obtained for N=1 and N=4 fit onto the respective predicted curves as seen in FIG. 24. This serves as a good verification of the model. It also gives an indication that for the s/d used in the four nozzle arrays, jet interaction does not play a significant role. If it did, then the correlation constants C and m found for the four nozzle array would not predict the correct heat transfer coefficient for the single nozzle. FIG. 24 also shows that the average heat transfer coefficients under the nine-nozzle arrays were much lower than predicted (curve 2404). The reason for this is believed to be as illustrated in FIG. 25, which shows a highly nonuniform local heat transfer distribution 2500 under the nine-nozzle array. The heat transfer coefficient was found to be highest under the central jet 2502, and to become lower for jets further away from the centre. The worst performance was found for the corner jets e.g. 2504. The bottom middle jet 2506 yielded a low heat transfer coefficient due to imperfections in the nozzle. In order to eliminate the effect of this, only the top half of the distribution was used in the calculation of h_{avg}.

It is likely that this pattern of nonuniform heat transfer between the different placement nozzles is caused by some form of jet interaction. Because s/d is only 3.57 for the nine-nozzle array, some amount of destructive interference prior to impingement is expected. The jet fountain effect may also play a role although it should not be significant at such low Reynolds numbers.

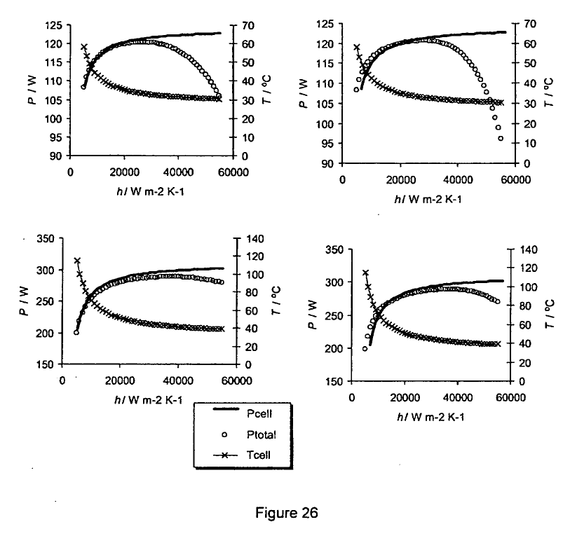

In addition, it seems from the pattern in FIG. 25 that the flow from the central jet drains diagonally between the middle jets 2508, 2510 and interferes with the corner jets e.g. 2504, resulting in a further deterioration in the corners. These findings serve to further emphasize the importance of keeping s/d>4 in preferred embodiments. FIGS. 26a-d show typical plots of the net PV output for different conditions. The dotted lines shows the PV output as a function of h_{avg}, while the full lines shows the change in cell temperature. It was found that a low average heat transfer coefficient results in a high cell temperature and a subsequent low cell output. The dotted lines show the net electrical output, which is the cell output minus the power required for the cooling system as given by the Martin (FIGS. 26a and c) and Huber model (FIG. 26b and d).

The pumping power is believed to be slightly underestimated because only the mechanical, not electrical, power requirement is calculated. The graphs in FIGS. 26a-d are based on an area of 50 mm×50 mm, and the parameters N=4, d=1.4 mm, C_{d}=6.1, C=1.96 and m=0.491. The cell properties are given in Table 4.

TABLE 4

| Layer | Material | Thickness t [m] | Thermal conductivity k [W m⁻¹ K⁻¹] | Total thermal resistance $R = \sum \frac{{t}_{i}}{{k}_{i}} [ K {m}^{2} {W}^{- 1} ]$ |
|---|---|---|---|---|
| Cover glass | Ceria-doped glass [14] | 3 × 10⁻³ | 1.4 [28] | |
| Adhesive | Optical grade RTV | 1 × 10⁻⁴ | 145 [11] | |
| | (room temperature | | | |
| | vulcanization) silicone | | | |
| | [14] | | | |
| Top half of | Silicon [14] | 6 × 10⁻⁵ [14] | 145 [11] | R_{g-c} = 2.14 × 10⁻³ |
| cell | | | | |
| Bottom half | Silicon [14] | 6 × 10⁻⁵ [14] | 145 [11] | |
| of cell | | | | |
| Solder | Sn:Pb:As: [11] | 1 × 10⁻⁴ [11] | 50 [11] | |
| Substrate | Aluminum nitride [14] | 2 × 10⁻³ [11] | 120 [14] | R_{c-s} = 1.91 × 10⁻⁵ |

Other parameters

| Symbol | Description | Value | Symbol | Description | Value |
|---|---|---|---|---|---|
| Tₐ | Ambient | 25° C. | R_{conv} | Convective thermal | 0.2 K m² W⁻¹ |
| | temperature | | | resistance | [11] |
| ε | Hemispherical | 0.855 [9] | a | Cell efficiency | 0.5546 [29] |
| | surface emissivity | | | parameter | |
| σ_{B} | Stephan- | 5.67 × 10⁻⁸ W m⁻² K⁻⁴ | b | Cell efficiency | 1.84 × 10⁻⁴ K⁻¹ |
| | Boltzmann | [28] | | parameter | [29] |
| | constant | | | | |
| S | Insolation | 1 × 10³ W m⁻² | | | |

From FIGS. 26a-d it can be seen that there is a definite optimal, although broad, h_{avg} at which the net electrical output reaches a maximum. The predictions from both the Martin and the Huber models are shown for concentration levels of for 200 and 500 suns. In this range there is not much difference between the two models. The Huber model predicts a lower W for a given h_{avg} below h_{avg}=42×103 W m⁻² K⁻¹ and a higher W above this level because the two models cross over as shown in FIG. 18. For a concentration level of 200 suns, the Martin model gives the optimal h_{avg} to be 27×103 W m⁻² K⁻¹ while the Huber model predicts it to be h_{avg}=28×103 W m⁻² K⁻¹. For 500 suns the same models predict the optimal h_{avg} to be found at 38 and 37×103 W m⁻² K⁻¹, respectively.

The design process in an example embodiment is outlined in the following steps, which are described more closely below:

1) Determine the size of the cooling unit, Lₕₑₐₜ,

2) Determine the number of nozzles, N,

3) Find a suitable nozzle-to-plate to diameter ratio, z/d,

4) Find the optimal nozzle diameter, d,

5) Determine the nozzle configuration and possible surface modifications, and

6) Find the optimal operating conditions.

The size of the cooling unit is an external parameter which is set by the size of the surface that needs to be cooled. For large arrays of closely packed, small PV cells, it can be preferable to build up the array of individual modules, each complete with one cooling unit. A practical size for a module could be about 100 mm×100 mm. The number of nozzles, N, should be made as high as possible while still being low enough to avoid negative crossflow effects. 3×3 arrays have been shown not to experience negative crossflow effects in example embodiments. The performance of 4×4 arrays may be slightly reduced, but considering the large increase in heat transfer that can be achieved by increasing the number of nozzles, the 4×4 arrays can probably be used with benefit. In the configuration with back drainage around all four sides, 4×4 may be used as the maximum number of nozzles for a unit cell. If another drainage configuration is used where exits for spent liquid are distributed throughout the array, such as for embodiments as described above with reference to FIG. 3, it may be preferable to use the highest possible number of nozzles, limited by s/d>4.

The nozzle-to-plate distance was kept at z/d=3.57 in the example embodiments but there is likely to be a benefit from reducing this distance. This will make the unit less bulky and may increase the array performance. The Martin model was found to be valid down to z/d=2, which is predicted to be the most favourable separation. Depending on manufacturing constraints, z/d=2 may be used as the optimal separation distance, with the possibility of being increased up to z/d=4 without a significant penalty.

In the next part of the design procedure in an example embodiment, the nozzle diameter dₒₚₜ is found as a function of Lₕₑₐₜ, N and z/d. If s/d is found to be below 4, the nozzle diameter or number of nozzles may be reduced. Reducing d may have a smaller impact on W, however a lower limit to d may be set for practical reasons. In addition to manufacturing constraints, perhaps the most important restriction on nozzle diameter may have to do with the clogging of the nozzles due to small particles in the coolant water. In example embodiments, the 0.7 mm nozzles had a tendency to be easily blocked. If no filter is used in the coolant circuit, the nozzle diameter may be at least 1.5 mm in example embodiment.

The choice of the parameters described above was found to be independent of nozzle configuration. When dₒₚₜ is determined, the next step is to decide on the type of nozzle. Countersinking the orifices from above or below is found to reduce W significantly in example embodiments, but the improvement has to be weighed up against the cost of an extra manufacturing step. Another factor to consider is surface modification. Surface modification can lead to as much as a threefold improvement in h_{avg} if done successfully. However, the type of modifications should be chosen with care, as some have been found to lead to a decrease in heat transfer. If a method of surface modification is known to increase the heat transfer to a level high enough to justify the extra manufacturing work, this may be included in the device design.

When the final design is selected, some experiments may be used for subsequent optimisation. One approach is to connect the cooling unit and the PV cells and run the assembly at a range of flow rates while monitoring the module short-circuit current, water temperature and pressure drop across the unit. If the properties of the PV cells are known, the average junction temperature can be inferred from the module short-circuit current in an example embodiment, and this in turn can be used to find h_{avg}. Other methods in different embodiments include thermographic liquid crystals or some other way of measuring the heated surface temperature. A series of measurements can give the heat transfer correlation constants C and m which are used in the Huber model and the discharge coefficient C_{d}. Orifices may be used as flow rate measurement devices and an extensive collection of data for C_{d} values for larger, standard orifice nozzles can be used in the design process.

The final stage of the optimisation procedure in an example embodiment is to find the optimal value of h_{avg} at which to run the cooling system. The electrical and thermal properties of the PV cells to be used in the system are incorporated in the model for PV output. To predict the required pumping power for the cooling system, the Huber model is used in the example embodiments using the constants C and m found in the above described measurements, because the Huber model is built on experimental data and thus may give more accurate predictions within the experimental range. By performing this final optimisation, one can find the optimal operating conditions for the system at any illumination level, and predict the typical electrical output for the chosen conditions according to example embodiments of the invention.

In a practical example embodiment, silicon PV cells may be kept below 60 degrees C. at all times. The impinging jets may typically have R in the range 10⁻⁴-10⁻⁶. The input water may be at about 20 degrees C. with the temperature of the output water a few degrees higher. The PV cells are maintained at ˜60 degrees C. in an example embodiment, where the concentration is such that without the cooling, the PV cells reach several hundred degrees C.

Since in such an example embodiment the PV cells are maintained below 60 degrees C., a boiling jet liquid design for PV cells using water cooling is not meaningful under those conditions. However, one could use a liquid with a low boiling point (e.g. 40-50 degrees or lower) with a high heat capacity and high thermal conductivity in different embodiments. In such embodiments aspects such as leaks, toxicity, non-open loop systems, dry-out of a two-phase device under high fluxes etc. are preferably considered.

A separate heat exchanger was used in example embodiments to take the heated water and cool it for returning to the cooling device. In a concentrating PV system, typically a field of mirrors will concentrate sunlight on to the PV cells at the focal point of the concentrator which will usually be some distance above the ground or base level and supported by the structure of the concentrator. The cooling device may thus be located at this same elevated point and the heat exchanger may be located on the ground or base level, connected to the cooling device by water pipes, in example embodiments.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

For example, while the example embodiment described relate to cooling of PV cells under high concentration, it will be appreciated that the present invention does have broader applications including cooling of mechanical and electroncis components and systems.

We claim:

1. An impinging liquid jet or jets cooling device arranged such that drainage of a jet liquid is in a direction substantially perpendicular to a surface to be cooled.

2. The device as claimed in claim 1, wherein the device comprises a submerged impinging jet or jets.

3. The device as claimed in claim 1, comprising an orifice plate disposed between first and second chambers of the device, wherein the jets are directed from the first chamber into the second chamber.

4. The device as claimed in claim 3, wherein the second chamber comprises a drainage passage for draining the jet liquid.

5. The device as claimed in claim 4, wherein the drainage passage is disposed at the sides of the second chamber, and the first chamber is disposed substantially centrally with respect to the second chamber.

6. The device as claimed in claim 4, wherein the drainage passage is disposed substantially centrally with respect to the second chamber, and the first chamber is disposed substantially around the drainage passage.

7. The device as claimed in claim 1, comprising one or more pipes disposed substantially parallel to the surface to be cooled.

8. The device as claimed in claim 7, wherein the pipes comprise one or more orifices for generating the jets, the orifices disposed at portions of the respective pipes closest to the surface to be cooled, in use.

9. The device as claimed in claim 8, further comprising two or more distributed drainage passages formed on sides of the pipes.

10. The device as claimed in claim 7, further comprising a feeder pipe in fluid communication with the pipes.

11. The device as claimed in claim 10, wherein the feeder pipe is disposed substantially perpendicular to the pipes and substantially parallel to the surface to be cooled.

12. The device as claimed in claim 11, wherein the feeder pipe comprises one or more orifices for generating the jets, the orifices being disposed at portions of the feeder pipe closest to the surface to be cooled, in use.

13. The device as claimed in claim 7, further comprising orifice channels formed on sides of the pipes and extending substantially perpendicular to the pipes towards the surface to be cooled for generating the jets.

14. The device as claimed in claim 13, wherein the pipes comprise one or more openings for draining the jet liquid through the pipes, the openings being disposed at portions of the respective pipes closest to the surface to be cooled, in use.

15. An impinging liquid jet or jets cooling device comprising multiple drainage channels for distributed drainage of an impinging jet liquid in a direction substantially perpendicular to a surface to be cooled.

16. A method of designing an impinging liquid jet or jets cooling device for cooling of photovoltaic cells under concentrated illumination, the method comprising:
selecting a pumping power for the device; and
selecting at least one design parameter such that an optimum heat transfer is achieved at the selected pumping power.

17. The method as claimed in claim 16, wherein the pumping power is selected based on a function of cell output power minus pumping power.

18. The method as claimed in claim 16, wherein the parameters comprise one or more of a group consisting of nozzle diameter, number of nozzles, size of surface to be cooled, distance of nozzles from surface to be cooled, nozzle shape, nozzle pitch, and nozzle array arrangement.

19. An impinging liquid jet or jets cooling device having a pumping power and comprising at least one design parameter selected such that an optimum heat transfer is achieved at the pumping power.

20. A photovoltaic cell system comprising:
a plurality of photovoltaic cells;
a concentrator for concentrating sunlight onto the photovoltaic cells; and
an impinging liquid jet or jets cooling unit thermally coupled to the photovoltaic cells via an interface comprising a surface and arranged such that drainage of a jet liquid is in a direction substantially perpendicular to the surface.

21. A photovoltaic cell system as claimed in claim 20, wherein the impinging liquid jet or jets cooling unit comprises a plurality of modules, each module coupled to one or more of the photovoltaic cells.
